(19) United States
(12) Patent Application Publication
(10) Pub. No.: US 2001/0028556 A1
(43) Pub. Date: Oct. 11, 2001

(54) Printed circuit board assembly

(76) Inventors: Qun Lu, Lexington, MA (US); Hanson Liu, Newton, MA (US)

Correspondence Address: FAUSTINO A. LICHAUCO, Fish & Richardson P.C., 225 Franklin Street, Boston, MA, 02110-2804, US

(21) Appl. No.: 09/739,167

(22) Filed: Dec. 18, 2000

Related U.S. Application Data
(63) Continuation of application No. 09/546,731, filed on Apr. 11, 2000.

(51) Int. Cl. H05K 1/11; H05K 1/14

(52) U.S. Cl. 361/760; 361/803; 361/792

(57) ABSTRACT

In printed circuit board fabrication, processing steps for components on one section of the board are sometimes incompatible with processing steps for components on another section of the board. The method of the invention provides for physically separate printed circuit board sections that are processed separately and joined together following processing. To provide electrical connection between a first component on a first printed circuit board section and a second component on a second printed circuit board section, the method of the invention includes the steps of connecting the first and second components to conducting regions disposed on edges of their respective printed circuit board sections. The two printed circuit board sections are then joined together so that the two conducting regions contact each other.

This invention relates to the manufacture of power converters, and in particular, to methods for connecting input/output pins to a power converter.

### BACKGROUND

A power converter typically includes a printed circuit board (PCB) on which are mounted various electrical components. These electrical components are connected to the outside world through I/O pins that are mounted on the printed circuit board. In conventional manufacturing practice, an I/O pin is soldered onto the printed circuit board.

In many cases, it is necessary to solder the pin to the board with a high-temperature solder. For example, if the printed circuit board is to undergo further processing in a wave-solder machine, the melting temperature of the solder used to secure the I/O pins to the board would have to exceed the temperature of the solder used in the wave-solder machine. Were this is not the case, the solder holding the I/O pins to the board would melt during the wave-soldering process and the I/O pins would fall off the board.

A difficulty associated with the practice of using a high-temperature solder to mount the I/O pins to the printed circuit board is that the high temperature associated with the soldering process can damage nearby electrical components on the board. This results in unacceptably high failure rates in the manufacturing process.

In another conventional method of mounting an I/O pin on a printed circuit board, the I/O pin is inserted into a hole whose diameter is such that the inner wall of the hole securely grips the I/O pin. Because the pin is thus mechanically held within the hole, there is no longer a need to rely on high-temperature solder to secure the pin. However, a disadvantage of the foregoing method is that the hole diameter and the pin diameter are so close to each other that the pin must be hammered into the hole. The large, impulsive forces generated in the process of hammering the I/O pin into the hole can disturb the electrical connections between other electrical components on the printed circuit board.

### SUMMARY OF THE INVENTION

The present invention advantageously provides a method for electrically connecting a first component on a first printed circuit board section with a second component on a second printed circuit board section physically separate from the first printed circuit board section. Because the two printed circuit board sections are physically separate, the processing steps applied to the first printed circuit board section do not affect the components on the second printed circuit board section. The completed printed circuit board can then be assembled from the first and second printed circuit board sections, each of which undergoes processing steps that are appropriate for the components mounted on that section.

The foregoing feature of the invention is achieved by a method that includes the step of providing electrical communication between the first component and a first conducting pad, or region, disposed on a first surface of the first printed circuit board section. The method further includes the analogous step of providing electrical communication between the second component and a second conducting pad, or region, disposed on a second surface of the second printed circuit board section. These two steps thus result in the fabrication of two printed circuit board sections, each of which has a conducting region on a surface. These conducting regions are in electrical communication with one or more elements on their corresponding printed circuit board sections.

The method of the invention further includes the step of soldering the two printed circuit board sections so that the first and second conducting regions make electrical contact. This is typically achieved by overlaying the first printed circuit board section on the second printed circuit board section so that the first and second conducting regions are in contact. In a preferred method, a low-temperature solder paste is placed on the second conducting region. Upon overlaying the first printed circuit board section onto the second printed circuit board section, the solder paste is heated so that it flows from the second conducting region to the first conducting region.

Preferably, the method includes the steps of forming a plated through-hole passing through a conducting path that contacts the first component. The plated-through hole thus formed intersects the first conducting region along a rim. In this preferred method, the hole is brought into alignment with the second conducting region so that the rim of the through-hole contacts the solder paste on the second conducting region. Upon being heated, the solder wicks into the plated through-hole, thereby providing secure electrical communication between the first and second components.

The present invention also includes a printed circuit board having a first section and a second section. The first section has a first component mounted in electrical communication with a first conducting region disposed at a bottom surface of the first section. Similarly, the second section has a second component mounted in electrical communication with a second conducting region disposed at a top surface of the second section. The first and second sections are integrally joined so that first conducting region contacts the second conducting region.

In a preferred embodiment, the first printed circuit board section includes a conducting path providing electrical communication between the first component and the first conducting region. To protect it from corrosion, the conducting path can be buried inside the first printed circuit board section. In such a case, the second conducting region includes a rim defining a plated hole extending between the first conducting path and the first conducting region. To provide a more secure electrical connection between the second conducting region and the conducting path, the preferred embodiment further includes a solder plug extending through the hole between the second conducting region and the first conducting path.

It is apparent therefore that the method and system of the invention enable the mounting of I/O pins on a printed circuit board without the risk of damaging other components on the board. These and other features and advantages of the invention will be apparent from the following description and the accompanying figures in which:

### BRIEF DESCRIPTION OF THE DRAWINGS

FIG. 1 is a planar view of first and second printed circuit board sections incorporating principles of the invention;

FIG. 2 is a cross-sectional view of the first and second printed circuit board sections shown in FIG. 1;

FIG. 3 shows the first and second printed circuit board sections of FIG. 2 joined together prior to soldering;

FIG. 4 shows the first and second printed circuit board sections of FIG. 3 after soldering;

FIG. 5 shows an embodiment in which an I/O pin is soldered onto the first printed circuit board section; and

FIG. 6 shows an embodiment in which no through-holes are used to provide electrical commutation between the first and second components.

### DETAILED DESCRIPTION

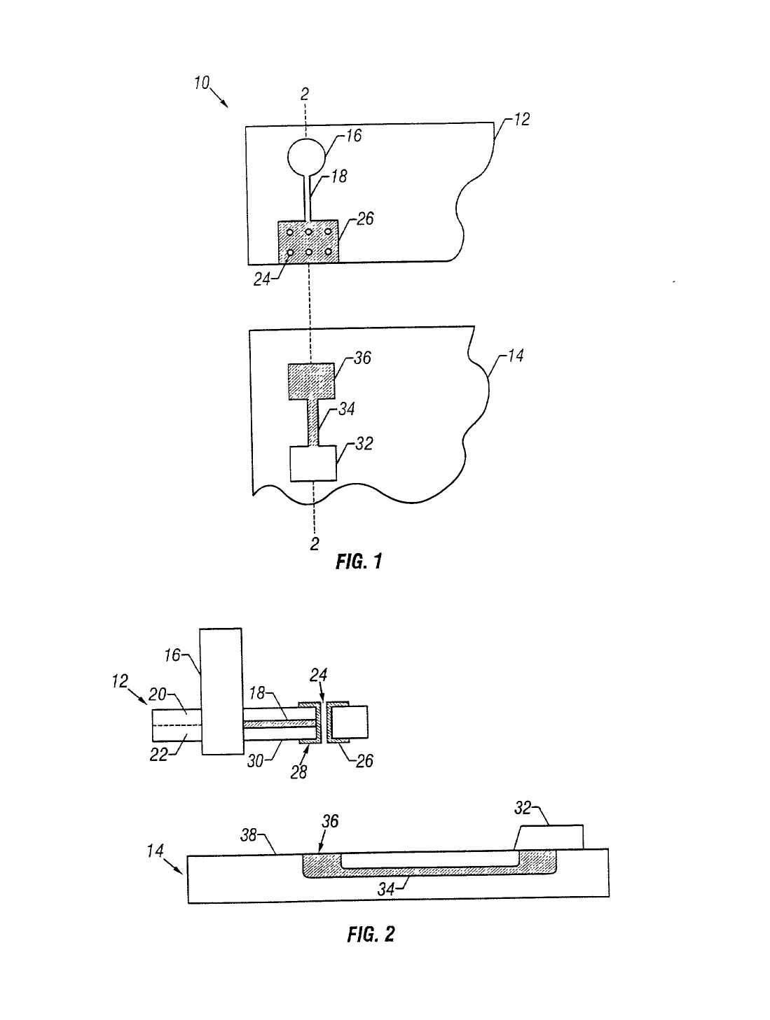

Prior to its assembly, a printed circuit board 10 according to the invention, as shown in FIG. 1, includes constituent first and second printed circuit board sections 12, 14. An I/O pin 16 mounted on the first printed circuit board section 12 is in electrical communication, with a first conducting path 18. To protect it from corrosion, the first conducting path 18 is typically sandwiched between first and second fiberglass layers 20, 22, best seen in the cross-sectional view of FIG. 2. One or more plated-through holes 24 penetrate the first and second fiberglass layers 20, 22 and the first conducting path 18. These through-holes 24 intersect, at a corresponding plurality of rims 26, a first conducting region 28 disposed on a bottom surface 30 of the first printed circuit board section 12. The plated through-holes 24 thus provide electrical communication between the first conduction region 28 and the first conducting path 18.

Referring again to FIG. 1, an electrical component 32 mounted on the second printed circuit board section 14 is in electrical communication, through a second conducting path 34, with a second conducting region 36 on a top surface 38 of the second printed circuit board section 14.

Because the first and second printed circuit board sections 12, 14 are separate from each other prior to assembly, each section can undergo separate processing steps without regard to the effect of those steps on the other section. As a result, a high-temperature solder can be used to secure the I/O pin 16 on the first printed circuit board section 12 without the risk of excessively heating any components on the second printed circuit board section 14. Alternatively, the I/O pin 16 can be hammered into position on the first printed circuit board section 12 without the risk that the forces thus generated will damage the second printed circuit board section 14.

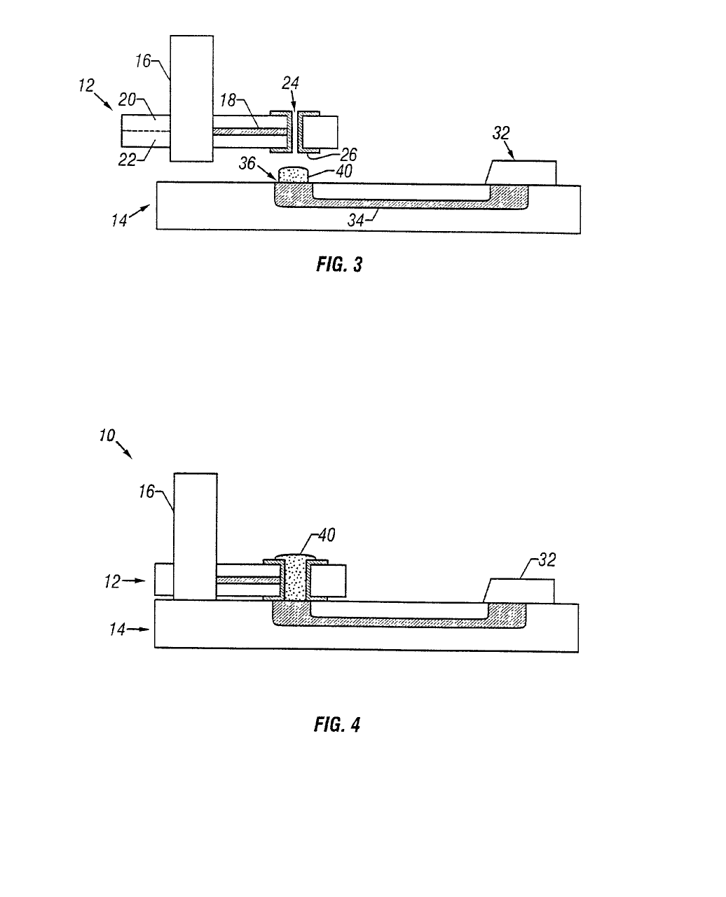

Following the placement and soldering of the I/O pin 16 on the first printed circuit board section 12, the first and second printed circuit board sections 12, 14, are joined together as shown in FIG. 3. This is achieved by placing a low-temperature solder paste 40 on the second conducting region 36 and overlaying the first section 12 onto the second section 14 so that the first conducting region 28 contacts the second conducting region 36. The solder paste 40 is then heated so that solder wicks up into the plated through-holes 28, as shown in FIG. 4. This results in a unitary printed circuit board 10 having an electrical connection between the I/O pin 16 on the first printed circuit board section 12 and the electrical component 32 on the second printed circuit board section 14.

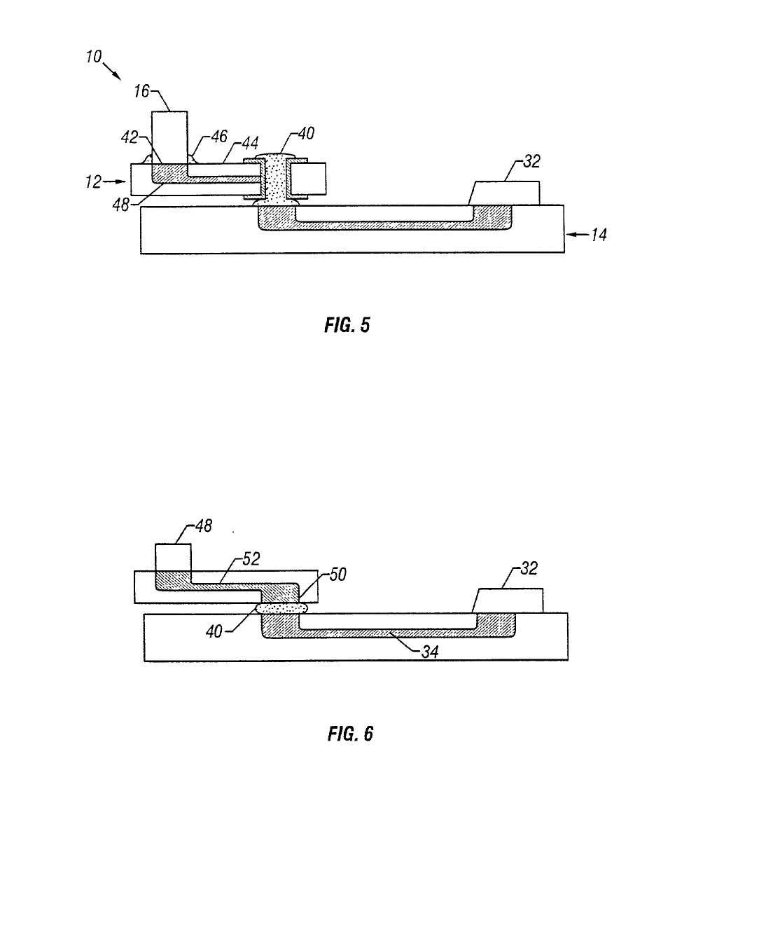

As shown in FIG. 2, the I/O pin 16 is staked through a hole in the first printed circuit board section 12. However, the I/O pin 16 can also be secured to the first printed circuit board section 12 by soldering it onto the first printed circuit board section 12. FIG. 5 shows the result of this alternative method of mounting the I/O pin 16 to the first printed circuit board section 12. Note that the I/O pin 16 rests on a conducting pad 42 on a top surface 44 of the first printed circuit board section and that a high-temperature solder 46 secures the I/O pin 16 to the conducting pad 42. A third conducting path 48 provides electrical communication between the conducting pad 42 and plated through-holes 24.

Although the preferred embodiment includes through-holes 24 for providing electrical communication between the I/O pin 16 on the first conducting region 28, such communications can be provided in other ways. For example, FIG. 6 shows an embodiment in which a first component 48 is in electrical communication with a conducting region 50 by a direct conducting path 52. The first component 48 can be an I/O pin as described in connection with the preferred embodiment. However, the first component 48 need not be an I/O pin and can in fact be any electrical component.

It will thus be seen that the foregoing method of connecting I/O pins to a printed circuit board in a power converter avoids the disadvantages of the prior art. In particular, by processing a printed circuit board section having the I/O pins mounted thereon separately from a printed circuit board section having the remaining electrical components mounted thereon, it is possible to eliminate the risk that the processing steps required to mount the I/O pins will damage other electrical components on the printed circuit board.

Having described the invention, and a preferred embodiment thereof, what we claim as new and secured by letters patent is:

1. A method for providing electrical communication between a first component on a first printed circuit board section and a second component on a second printed circuit board section, said method comprising the steps of:
providing electrical communication between said first component and a first conducting region disposed on a first surface of said first printed circuit board section;
providing electrical communication between said second component and a second conducting region disposed on a second surface of said second printed circuit board section; and
soldering said first and said second printed circuit board sections such that said first conducting region contacts said second conduction region.

2. The method for claim 1 further comprising the step of selecting said first component to be an I/O pin.

3. The method of claim 1 wherein said step of providing electrical communication between said first component and said first conducting region comprises the step of providing a conducting path between said first component and said first conducting region.

4. The method of claim 3 wherein said step of providing electrical communication between said first component and said first conducting region further comprises the step of providing a plated hole through said conducting path said hole intersecting said first conduction region at a rim

5. The method of claim 1 wherein said step of joining said first and second printed circuit board sections comprises the steps of
providing a solder paste on said second conducting region;
overlaying said first printed circuit board section on said second printed circuit board section such that said first conducting region contacts said second conducting region; and
heating said solder paste such that melted solder flows from said second conducting region to said first conducting region

6. The method of claim 4 wherein said step of joining said first and second printed circuit board sections comprises the steps of:
providing solder paste on said second conducting region;
overlaying said first printed circuit board section on said second printed circuit board section such that said rim is aligned with said second conducting region; and
heating said solder paste such that melted solder wicks into said plated through-hole, thereby providing electrical communication between said first and second components.

7. The method of claim 3 wherein said step of providing electrical communication between said first conducting region and said first component comprises the steps providing a plurality of plated through-holes through said conducting path, said plated through-holes intersecting said first conducting region at a corresponding plurality of rims.

8. The method of claim 7 wherein said step of joining said first and second printed circuit board sections comprises the steps of:
providing solder paste on said second conducting region;
overlaying said first printed circuit board section on said second printed circuit board section such that said plurality of rims is aligned with said second conducting region; and
heating said solder paste such that melted solder wicks into said plurality of plated through-holes.

9. A printed circuit board comprising:
a first printed circuit board section having a first component mounted thereon, said first component being in electrical communication with a first conducting region disposed on a bottom surface of said first printed circuit board section;
a second printed circuit board section having a second component mounted thereon, said second component being in electrical communication with a second conducting region disposed at a top surface of said second printed circuit board section, said second printed circuit board section being integrally joined to said first printed circuit board section such that said first conducting region contacts said second conducting region.

10. The printed circuit board of claim 9 wherein said first component is an I/O pin.

11. The printed circuit board of claim 9 wherein said first printed circuit board section further comprises a conducting path in electrical communication with said first component and said first conducting region.

12. The printed circuit board of claim 11 wherein said first conducting path is buried inside said first printed circuit board section and said second conducting region includes a rim defining a plated hole extending between said first conducting path and said first conducting region.

13. The printed circuit board of claim 12 further comprising a solder plug extending through said hole and providing electrical communication between said second conducting region and said first conducting path.
